(19) United States
(12) Patent Application Publication
(10) Pub. No.: US 2024/0196666 A1
(43) Pub. Date: Jun. 13, 2024

(54) DISPLAY PANEL AND METHOD OF MANUFACTURING THE SAME

(71) Applicant: LG DISPLAY CO., LTD., Seoul (KR)

(72) Inventors: Byung Yong AHN, Paju-si (KR); Won So SON, Paju-si (KR); Chang Hyeon CHO, Paju-si (KR)

(73) Assignee: LG DISPLAY CO., LTD., Seoul (KR)

(21) Appl. No.: 18/236,136

(22) Filed: Aug. 21, 2023

(30) Foreign Application Priority Data
Dec. 8, 2022 (KR) 10-2022-0170590

(51) Int. Cl. H10K 59/124; H10K 59/12; H10K 59/121

(52) U.S. Cl. CPC H10K 59/124; H10K 59/1201; H10K 59/1213

(57) ABSTRACT

Disclosed are a display panel, which is capable of reducing mura at low grayscale, and a method of manufacturing the same. The thickness of a gate insulating layer of a driving thin-film transistor is increased, and the mobility of the driving thin-film transistor is reduced to reduce the K-factor of the driving thin-film transistor. The display panel includes a plurality of sub-pixels, each having a driving thin-film transistor, a switching thin-film transistor, and a storage capacitor on a substrate. The driving thin-film transistor includes a semiconductor layer comprising a source region and a drain region; a gate electrode overlapping the semiconductor layer; a source electrode and a drain electrode electrically connected to the source region and the drain region; and a gate insulating layer located between the semiconductor layer and the gate electrode. The semiconductor layer is a dehydrogenated semiconductor layer.

This application claims the benefit of Korean Patent Application No. 10-2022-0170590, filed on Dec. 8, 2022, which is hereby incorporated by reference as if fully set forth herein.

### BACKGROUND

### Technical Field

The present disclosure relates to a display panel, which is capable of reducing mura at low grayscale, and a method of manufacturing the same.

### Discussion of the Related Art

Recently, with the arrival of the information age, the field of displays for visually displaying electrically conveyed information signals has developed rapidly. In response to this, organic light-emitting display devices have recently attracted attention.

An organic light-emitting display device includes two electrodes and an emission layer disposed therebetween. Electrons injected from one electrode and holes injected from the other electrode are combined with each other in the emission layer to form excitons, and a self-emissive element such as an organic light-emitting diode emits light in response to emission of energy from the excitons, whereby images are displayed.

By virtue of the self-emissive element, the organic light-emitting display device may have a high response speed, high luminance, and low driving voltage, may be ultra-thin, and may be implemented in a free shape.

The organic light-emitting display device includes a display panel, which includes data lines, scan lines, and a plurality of sub-pixels formed at intersections between the data lines and the scan lines, a gate driver for supplying scan signals to the scan lines, and a data driver for supplying data voltages to the data lines.

Each of the sub-pixels includes an organic light-emitting diode and a pixel circuit for independently driving the organic light-emitting diode.

The pixel circuit includes a driving transistor for adjusting the amount of current supplied to the organic light-emitting diode depending on voltage of a gate electrode, and a scan transistor for supplying the data voltage of the data line to the gate electrode of the driving transistor in response to the scan signal of the scan line.

### SUMMARY

Accordingly, embodiments of the present disclosure are directed to a display panel and a method of manufacturing the same that substantially obviate one or more problems due to limitations and disadvantages of the related art.

An aspect of the present disclosure is to provide a display panel, which is capable of preventing occurrence of mura at low grayscale through improvement of the characteristics of a driving thin-film transistor, and a method of manufacturing the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display panel comprises a plurality of sub-pixels, each having a driving thin-film transistor, a switching thin-film transistor, and a storage capacitor on a substrate, wherein the driving thin-film transistor includes a semiconductor layer including a source region and a drain region, a gate electrode overlapping the semiconductor layer, source and drain electrodes electrically connected to the source and drain regions, and a gate insulating layer located between the semiconductor layer and the gate electrode, and wherein the semiconductor layer is a dehydrogenated semiconductor layer.

Here, the semiconductor layer may have a mobility of 79 cm²/Vs to 82 cm²/Vs.

The gate insulating layer may have a thickness of 1500 Å to 1700 Å.

The driving thin-film transistor may have a smaller K-factor than the switching thin-film transistor.

Each of the plurality of sub-pixels may further include an organic light-emitting diode electrically connected to the drain electrode of the driving thin-film transistor.

In another aspect, a method of manufacturing a display panel comprises forming a semiconductor layer on a substrate, patterning the semiconductor layer to form a first semiconductor layer for a driving thin-film transistor and a second semiconductor layer for a switching thin-film transistor, performing heat treatment for dehydrogenation on the first semiconductor layer to remove hydrogen coupled to a surface of the first semiconductor layer, forming a gate insulating layer on an entire surface of the substrate having the first and second semiconductor layers formed thereon, and etching a remaining portion of the gate insulating layer, except for a portion of the gate insulating layer formed on the first semiconductor layer, to a predetermined depth.

The first semiconductor layer may be subjected to heat treatment for 10 to 20 minutes at a temperature ranging from 370° C. to 374° C.

In another aspect of the present disclosure, a display panel comprises: a plurality of sub-pixels, each having a driving thin-film transistor, a switching thin-film transistor, and a storage capacitor on a substrate, wherein the driving thin-film transistor and the switching thin-film transistor each comprise a semiconductor layer, a gate electrode, and a gate insulating layer located between the semiconductor layer and the gate electrode, wherein the gate insulating layer of the driving thin-film transistor is formed to be thicker than the gate insulating layer of the switching thin-film transistor, and the semiconductor layer of the driving thin-film transistor is a dehydrogenated semiconductor layer.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles of the disclosure. In the drawings:

FIG. 1 is an equivalent circuit diagram of an organic light-emitting display device including a display panel according to an embodiment of the present disclosure;

FIG. 2 is a cross-sectional view showing the structure of a display panel according to an embodiment of the present disclosure;

FIGS. 3 to 11 are cross-sectional views showing an embodiment of processes of manufacturing the display panel shown in FIG. 2;

FIG. 12 is a table showing results of measuring the mobility of a driving thin-film transistor according to the present disclosure depending on heat treatment temperature and time;

FIG. 13 is a graph showing change in K-factor depending on the thickness of a gate insulating layer of the driving thin-film transistor according to the present disclosure;

FIG. 14 is a graph showing change in K-factor depending on the mobility of the driving thin-film transistor according to the embodiment of the present disclosure; and

FIG. 15 is a table showing change in K-factor depending on the mobility of the driving thin-film transistor and the thickness of the gate insulating layer according to the embodiment of the present disclosure.

### DETAILED DESCRIPTION

Advantages and features of the present disclosure and methods for achieving them will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the disclosure to those skilled in the art. The present disclosure is defined only by the scope of the claims.

In the drawings for explaining the exemplary embodiments of the present disclosure, for example, the illustrated shape, size, ratio, angle, and number are given by way of example, and thus, are not limited to the disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear.

The terms “comprises,” “includes,” and/or “has”, used in this specification, do not preclude the presence or addition of other elements unless used along with the term “only”. The singular forms are intended to include the plural forms as well, unless the context clearly indicates otherwise.

In the interpretation of constituent elements, the constituent elements are interpreted as including an error range even if there is no explicit description thereof.

In the description of the various embodiments, when describing positional relationships, for example, when the positional relationship between two parts is described using “on”, “above”, “below”, “next to”, or the like, one or more other parts may be located between the two parts unless the term “directly” or “closely” is used.

The terms “first”, “second”, etc. may be used to distinguish various components. However, functions or structures of the components are not limited by names of the components or ordinal numbers prefixed to the component names. Since essential components are mainly stated in the claims, ordinal numbers prefixed to names of the components stated in the claims may not match ordinal numbers prefixed to names of the components described in embodiments of the disclosure.

The features of embodiments of the disclosure can be partially combined or entirely combined with each other, and can be technically interlocking-driven in various ways. The embodiments can be independently implemented, or can be implemented in conjunction with each other.

Hereinafter, a display panel and a method of manufacturing the same of the present disclosure will be described in detail with reference to the accompanying drawings.

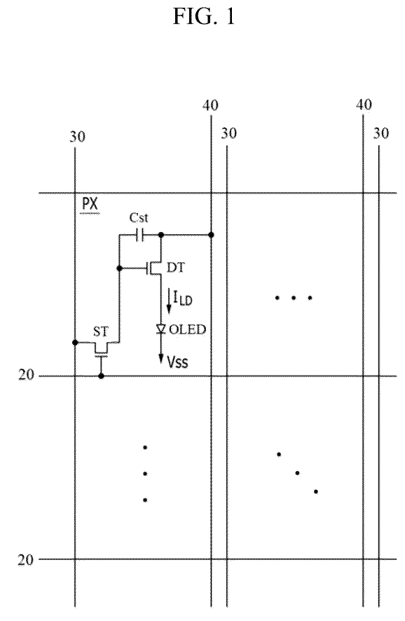

FIG. 1 is an equivalent circuit diagram of an organic light-emitting display device including a display panel according to an embodiment of the present disclosure.

As shown in FIG. 1, the display panel according to an embodiment of the present disclosure includes a plurality of gate lines 20 arranged in a first direction, a plurality of data lines 30 arranged in a second direction different from the first direction, a plurality of driving voltage supply lines 40 arranged in the second direction, and a plurality of sub-pixels PX connected to the plurality of gate lines 20, the plurality of data lines 30, and the plurality of driving voltage supply lines 40 so as to be arranged in a matrix form.

Each of the sub-pixels PX includes a switching thin-film transistor ST, a driving thin-film transistor DT, a storage capacitor Cst, and an organic light-emitting diode OLED. The switching thin-film transistor ST, the driving thin-film transistor DT, and the storage capacitor Cst may be formed on a substrate, and the organic light-emitting diode OLED may be formed on the switching thin-film transistor ST, the driving thin-film transistor DT, and the storage capacitor Cst.

Although not shown in the drawings, one sub-pixel PX may further include an additional thin-film transistor and an additional capacitor in order to sense and compensate for deterioration of the organic light-emitting diode OLED or the mobility and threshold voltage of the driving thin-film transistor DT.

Each of the switching thin-film transistor ST and the driving thin-film transistor DT may include a gate electrode and first and second electrodes.

The gate electrode of the switching thin-film transistor ST is connected to the gate line 20, the first electrode is connected to the data line 30, and the second electrode is connected to the gate electrode of the driving thin-film transistor DT and to the storage capacitor Cst.

The switching thin-film transistor ST transmits the data voltage received from the data line 30 to the gate electrode of the driving thin-film transistor DT and to the storage capacitor Cst in response to the scan signal received from the gate line 20.

The gate electrode of the driving thin-film transistor DT is connected to the switching thin-film transistor ST, the first electrode is connected to the driving voltage supply line 40, and the second electrode is connected to the organic light-emitting diode OLED. The current I_{LD} flowing through the driving thin-film transistor DT is controlled depending on the voltage between the gate electrode of the driving thin-film transistor DT and the second electrode of the driving thin-film transistor DT.

The storage capacitor Cst is connected between the gate electrode of the driving thin-film transistor DT and the first electrode of the driving thin-film transistor DT. The storage capacitor Cst charges the data voltage applied to the gate electrode of the driving thin-film transistor DT, and maintains the data voltage after the switching thin-film transistor ST is turned off, thereby maintaining a light-emission state of the organic light-emitting diode OLED until the next data voltage is applied.

The organic light-emitting diode OLED includes an anode connected to the second electrode of the driving thin-film transistor DT and a cathode connected to a ground voltage or a common voltage Vss. The organic light-emitting diode OLED may emit light while changing the intensity of the light depending on the current I_{LD} of the driving thin-film transistor DT, thereby displaying an image.

A relatively small S-factor is advantageous to increase the driving speed of the switching thin-film transistor ST, and a relatively large S-factor is advantageous to reduce luminance variation attributable to gate voltage distribution in the driving thin-film transistor DT. Here, the term “S-factor” as a current-voltage characteristic of a thin-film transistor may indicate the magnitude of gate voltage required to increase the drain current by 10 times when gate voltage of less than threshold voltage is applied. The S-factor may generally be referred to as a “sub-threshold slope.”

Recently, customers have demanded display panels with low power consumption. Accordingly, the luminous efficiency of light-emitting devices has increased, and current Ids of driving thin-film transistors for implementing low grayscale has decreased. Accordingly, the current (Ids) sensitivity of the driving thin-film transistor increases, thereby causing vulnerability to mura at low grayscale.

Further, there is a limitation on the extent to which current (Ids) distribution of the driving thin-film transistor DT is improved through improvement of the S-factor and process conditions (a deposition thickness or the like).

Therefore, it is necessary to reduce the current (Ids) sensitivity of the driving thin-film transistor DT to improve mura at low grayscale.

The current Ids of the driving thin-film transistor DT is defined as shown in equation 1 below.

$$Ids = \frac{1}{2} μ Cox \frac{W}{L} {( V gs - V th )}^{2} \qquad [ Equation 1 ]$$

Here, “Ids” represents the current of the driving thin-film transistor DT, “Vgs” represents the gate-source voltage of the driving thin-film transistor DT, “Vth” represents the threshold voltage of the driving thin-film transistor DT, “Cox” represents the parasitic capacitance between the gate electrode of the driving thin-film transistor DT and a semiconductor layer (an active layer), and “μ” represents the mobility of the driving thin-film transistor DT.

Therefore, a K-factor may be defined as shown in equation 2 below.

$$K - factor = \frac{Ids}{{( V gs - V th )}^{2}} \qquad [ Equation 2 ]$$

The K-factor may be calculated from equation 2 above.

A case of calculating the K-factor in a mobile OLED model in which the thickness of the gate insulating layer of the driving thin-film transistor DT is 1480 Å and the mobility u of the driving thin-film transistor DT is 87.58 will now be described by way of example.

In the above model, the current Ids of the driving thin-film transistor DT in a low grayscale region is 241 pA. In addition, the threshold voltage Vth of the driving thin-film transistor DT may be measured using a method of compensating for the threshold voltage of the driving thin-film transistor. In addition, the gate-source voltage Vgs of the driving thin-film transistor DT may be calculated as a voltage value corresponding to 241 pA in a transfer curve indicating the relationship between voltage V applied to the gate electrode of the driving thin-film transistor and current I of the driving thin-film transistor DT corresponding thereto.

The K-factor may be calculated under the above conditions.

The display panel of the present disclosure reduces variation in the current Ids of the driving thin-film transistor attributable to distribution of the gate-source voltage Vgs of the driving thin-film transistor DT and the threshold voltage Vth of the driving thin-film transistor DT by reducing the K-factor. That is, it is possible to prevent mura at the time of low grayscale driving by reducing the current (Ids) sensitivity of the driving thin-film transistor.

A display panel and a method of manufacturing the same according to embodiments of the present disclosure for accomplishing the above objects will be described below in detail.

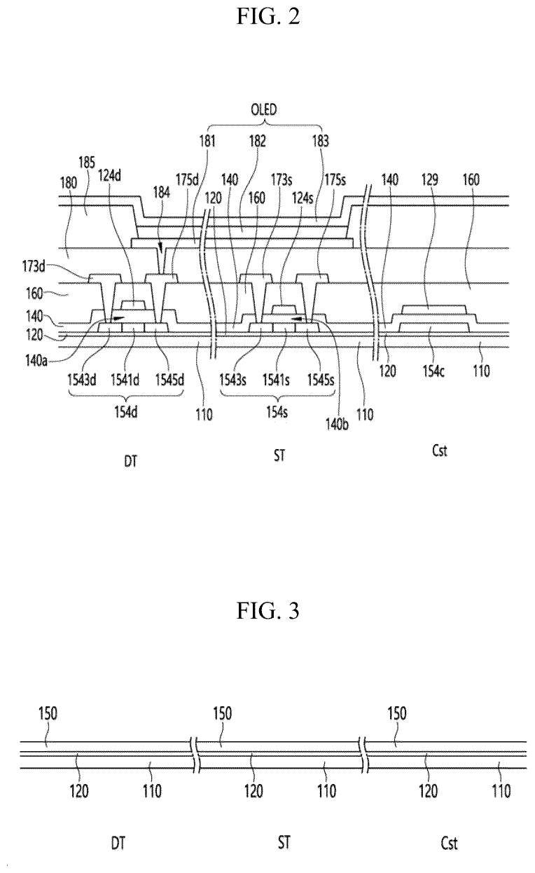

FIG. 2 is a cross-sectional view showing the structure of a display panel according to an embodiment of the present disclosure.

An organic light-emitting display panel will be described as the display panel according to the embodiment of the present disclosure.

As shown in FIG. 2, the organic light-emitting display panel according to the embodiment of the present disclosure includes a switching thin-film transistor ST, which is disposed on a substrate 110 to be connected to the gate line (20 in FIG. 1) and the data line (30 in FIG. 1), an organic light-emitting diode OLED, which includes an anode 181, a light emission layer 182, and a cathode 183, a driving thin-film transistor DT, which is connected to the anode 181, the switching thin-film transistor ST, and the driving voltage supply line (40 in FIG. 1), and a storage capacitor Cst, which is connected to the switching thin-film transistor ST and the driving thin-film transistor DT.

The driving thin-film transistor DT and the switching thin-film transistor ST may be polysilicon (poly-Si) thin-film transistors.

The substrate 110 may be a glass substrate or a plastic substrate.

The driving thin-film transistor DT includes a semiconductor layer 154d, a gate electrode 124d, a source electrode 173d, and a drain electrode 175d. The driving thin-film transistor DT may be referred to as a top-gate thin-film transistor because the gate electrode 124d is located above the semiconductor layer 154d. In some embodiments, the driving thin-film transistor may be a bottom-gate thin-film transistor in which a gate electrode is located below a semiconductor layer.

A gate insulating layer 140a is interposed between the semiconductor layer 154d and the gate electrode 124d, and an interlayer insulating layer 160 is interposed between the gate electrode 124d and the source and drain electrodes 173d and 175d.

The semiconductor layer 154d includes a source region 1543d and a drain region 1545d, which are formed at respective lateral ends of the semiconductor layer 154d and are doped with impurities. The source region 1543d and the drain region 1545d are electrically connected to the source electrode 173d and the drain electrode 175d, respectively, through contact holes formed through the interlayer insulating layer 160 and the gate insulating layer 140a.

A blocking layer 120 may be located between the substrate 110 and the semiconductor layer 154d. The blocking layer 120 may include a barrier layer or a buffer layer.

The switching thin-film transistor ST includes a semiconductor layer 154s, a gate electrode 124s, a source electrode 173s, and a drain electrode 175s.

Similar to the driving thin-film transistor DT, the gate insulating layer 140b is interposed between the semiconductor layer 154s and the gate electrode 124s, and the interlayer insulating layer 160 is interposed between the gate electrode 124s and the source and drain electrodes 173s and 175s.

Here, the thickness of the gate insulating layer 140a of the driving thin-film transistor DT may be greater than the thickness of the gate insulating layer 140b of the switching thin-film transistor ST.

For example, the gate insulating layer 140a of the driving thin-film transistor DT may have a thickness of about 1600 Å, preferably from 1500 Å to 1700 Å.

The gate insulating layer 140b of the switching thin-film transistor ST may have a thickness of about 1480 Å, preferably from 1450 Å to 1510 Å.

In addition, the semiconductor layer 154d of the driving thin-film transistor DT may be formed to be different from the semiconductor layer 154s of the switching thin-film transistor ST.

That is, the semiconductor layer 154d of the driving thin-film transistor DT is formed by performing contact (CNT) heat treatment on a portion hydrogen-bonded to the semiconductor layer through dangling bonds to dehydrogenate the same. That is, when the semiconductor layer is subjected to CNT heat treatment, hydrogen bonded to a surface of the semiconductor layer 154d by dangling bonding is removed.

A blocking layer 120 may be located between the substrate 110 and the semiconductor layer 154s.

The semiconductor layer 154s includes a source region 1543s and a drain region 1545s, which are formed at respective lateral ends of the semiconductor layer 154s and are doped with impurities. The source region 1543s and the drain region 1545s are electrically connected to the source electrode 173s and the drain electrode 175s, respectively, through contact holes formed through the interlayer insulating layer 160 and the gate insulating layer 140b.

The storage capacitor Cst may include a first electrode 154c implemented as a semiconductor doped with an impurity and a second electrode 129 overlapping the first electrode 154c, with the gate insulating layer 140 interposed therebetween. The interlayer insulating layer 160 may be located on the second electrode 129, and the blocking layer 120 may be located between the substrate 110 and the first electrode 154c. In some embodiments, the storage capacitor Cst may further include a third electrode (not shown) overlapping the second electrode 129, with the interlayer insulating layer 160 interposed therebetween.

FIGS. 3 to 11 are cross-sectional views sequentially showing processes of manufacturing the display panel according to an embodiment of the present invention.

A method of manufacturing a thin-film transistor array panel according to an embodiment of the present disclosure will now be described with reference to FIGS. 3 to 11.

As shown in FIG. 3, a blocking layer 120 is formed on a substrate 110, and a polysilicon layer 150 is formed on the blocking layer 120.

The substrate 110 is made of a transparent insulating material such as glass or plastic. For example, the substrate 110 may be made of borosilicate-based glass having a heat resistance temperature of 600° C. or higher. The substrate 110 may be a plastic substrate made of polyethylene terephthalate (PET), polyethylene naphthalate (PEN), or polyimide, and the plastic substrate may be a flexible substrate.

The blocking layer 120 may be referred to as a barrier layer or a buffer layer, and may be formed in order to prevent diffusion of an impurity degrading the characteristics of a semiconductor, prevent infiltration of moisture or outside air, and planarize a surface. The blocking layer 120 may be formed by depositing SiOx, SiNx, or the like in a single layer or multiple layers through a deposition method such as plasma enhanced chemical vapor deposition (PECVD), atmospheric pressure chemical vapor deposition (APCVD), or low pressure chemical vapor deposition (LPCVD). The blocking layer 120 may be omitted depending on the type of the substrate or process conditions.

The polysilicon layer 150 may be formed by depositing amorphous silicon (a-Si) through, for example, a PECVD method, performing dehydrogenation treatment to remove hydrogen included in the amorphous silicon, and forming a polysilicon (poly-Si) state through a laser crystallization method such as excimer laser annealing (ELA). As a method of forming polysilicon, a thermal crystallization method such as solid phase crystallization (SPC), super grain silicon (SGS) crystallization, metal induced crystallization (MIC), or metal induced lateral crystallization (MILC) may be used as an alternative to laser crystallization.

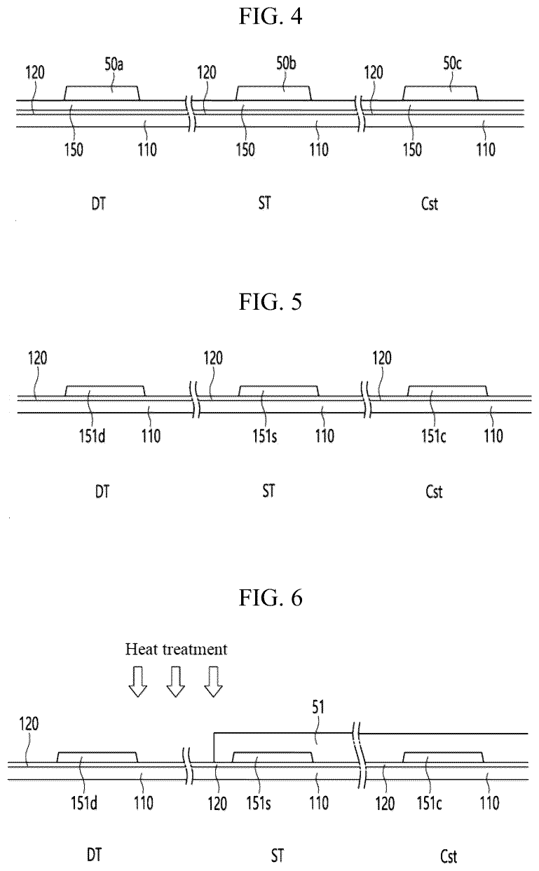

As shown in FIG. 4, a photoresist film is stacked on the polysilicon layer 150, and thereafter, a first photoresist film pattern 50a, a second photoresist film pattern 50b, and a third photoresist film pattern 50c are formed through a photolithography process.

The first photoresist film pattern 50a is formed at a position at which the semiconductor layer 154d of the driving thin-film transistor DT is to be formed, the second photoresist film pattern 50b is formed at a position at which the semiconductor layer 154s of the switching thin-film transistor ST is to be formed, and the third photoresist film pattern 50c is formed at a position at which the first electrode 154c of the storage capacitor Cst is to be formed.

As shown in FIG. 5, the polysilicon layer 150 is etched using the first, second, and third photoresist film patterns 50a, 50b, and 50c as a mask to form a driving semiconductor layer 151d, which is to become a semiconductor layer 154d of the driving thin-film transistor DT, a switching semiconductor layer 151s, which is to become a semiconductor layer 154s of the switching thin-film transistor ST, and a capacitor semiconductor layer 151c, which is to become a first electrode 154c of the storage capacitor Cst. Dry etching or wet etching may be performed as the etching. However, in many cases, dry etching is performed on low-temperature polysilicon because the pattern accuracy thereof is high.

As shown in FIG. 6, all of the first, second, and third photoresist film patterns 50a, 50b, and 50c are removed, a photoresist film is stacked on the entire surface of the substrate, on which the driving semiconductor layer 151d, the switching semiconductor layer 151s, and the capacitor semiconductor layer 151c are formed, and a fourth photoresist film pattern 51 is formed through a photolithography process.

The fourth photoresist film pattern 51 exposes the driving semiconductor layer 151d and covers the switching semiconductor layer 151s and the capacitor semiconductor layer 151c.

Thereafter, heat treatment for dehydrogenation is performed on the exposed driving semiconductor layer 151d in an N₂ gas atmosphere to remove hydrogen (H) coupled (or bonded) to the surface of the driving semiconductor layer 151d through dangling bonds.

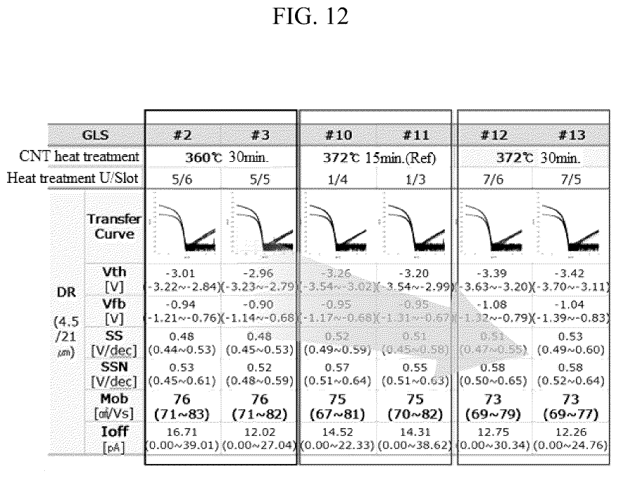

FIG. 12 is a table showing results of measuring the mobility of the driving thin-film transistor according to the present disclosure depending on heat treatment temperature and time.

It can be seen that, as heat treatment temperature and time increase, the mobility of the driving thin-film transistor DT decreases.

That is, in the case of a mobile OLED model, when heat treatment is performed for 15 minutes at a temperature of 372° C., the mobility of the driving thin-film transistor DT decreases compared to when heat treatment is performed for 30 minutes at a temperature of 360° C. In addition, when heat treatment is performed for 30 minutes at a temperature of 372° C., the mobility of the driving thin-film transistor DT further decreases compared to when heat treatment is performed for 15 minutes at a temperature of 372° C.

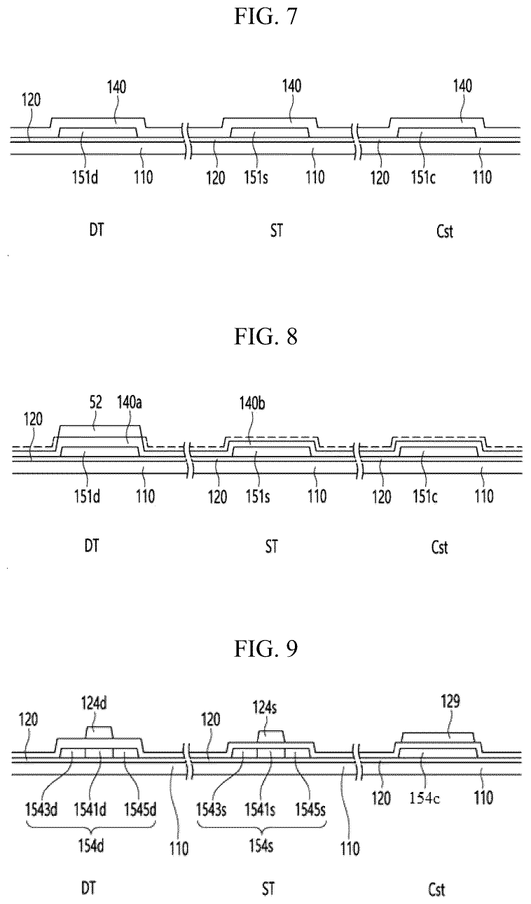

As shown in FIG. 7, the fourth photoresist film pattern 51 is removed, and thereafter, a gate insulating layer 140 is formed on the entire surface of the substrate, on which the driving semiconductor 151d, layer the switching semiconductor layer 151s, and the capacitor semiconductor layer 151c are formed. The gate insulating layer 140 may be formed of an inorganic insulating material such as SiOₓ, SiNₓ, SiONₓ, Al₂O₃, TiO, Ta₂O₅, HfO₂, ZrO₂, BST, or PZT through a deposition method such as PECVD, LPCVD, APCVD, or electron cyclotron resonance chemical vapor deposition (ECR-CVD).

As shown in FIG. 8, a photoresist film is stacked on the gate insulating layer 140, and thereafter, a fifth photoresist film pattern 52 is formed through a photolithography process. The fifth photoresist film pattern 52 remains only on the driving semiconductor layer 151d so as to cover a portion of the gate insulating layer 140 that is located on the driving semiconductor layer 151d and to expose the remaining portion of the gate insulating layer 140.

The exposed portion of the gate insulating layer 140 is etched by a predetermined thickness using the fifth photoresist film pattern 52 as a mask.

For example, in FIG. 8, the gate insulating layer 140 is formed to have a thickness of 1500 Å to 1700 Å, and the exposed portion thereof is etched by a thickness of about 120 Å.

Accordingly, the gate insulating layer 140a formed on the driving semiconductor layer 151d may have a thickness of 1500 Å to 1700 Å, and the gate insulating layer 140b formed on the switching semiconductor layer 151s and the capacitor semiconductor layer 151c may have a thickness of 1380 Å to 1580 Å.

In other words, in FIG. 8, when the gate insulating layer 140 is formed to have a thickness of about 1600 Å, the gate insulating layer 140a formed on the driving semiconductor layer 151d may have a thickness of about 1600 Å, and the gate insulating layer 140b formed on the switching semiconductor layer 151s and the capacitor semiconductor layer 151c may have a thickness of about 1480 Å.

As shown in FIG. 9, the fifth photoresist film pattern 52 is removed, and thereafter, a gate electrode 124d of the driving thin-film transistor DT, a gate electrode 124s of the switching thin-film transistor ST, and a second electrode 129 of the storage capacitor Cst are formed on the gate insulating layers 140a and 140b. The gate electrode 124d of the driving thin-film transistor DT may be formed so as to overlap a channel region 1541d of the semiconductor layer 154d, the gate electrode 124s of the switching thin-film transistor ST may be formed so as to overlap a channel region 1541s of the semiconductor layer 154s, and the second electrode 129 of the storage capacitor Cst may be formed so as to overlap a first electrode 154c.

In addition, source regions 1543d and 1543s and drain regions 1545d and 1545s of the semiconductor layers 154d and 154s of the driving and switching thin-film transistors DT and ST and a first electrode 154c of the storage capacitor Cst are formed through impurity doping.

In some embodiments, the capacitor semiconductor layer 151c, which is to become the first electrode 154c of the storage capacitor Cst, may be subjected to doping before the second electrode 129 is formed.

The impurity may be a p-type impurity such as a boron (B) ion or an n-type impurity such as a phosphorus (P) ion. Activation treatment may be performed after impurity doping.

The gate electrodes 124d and 124s may be formed as a conductive metal film including, for example, Al, Cu, Mo, W, Cr, or alloys thereof, but the disclosure is not necessarily limited thereto. Any of various conductive materials including a conductive polymer may be used as well as or as an alternative to the metal material.

In addition, the gate electrodes 124d and 124s may be formed of a transparent conductive material such as indium tin oxide (ITO), indium zinc oxide (IZO), or ZnO. The gate electrodes 124d and 124s may have a multilayer structure, for example, a dual-layer structure. In this case, a lower layer may be made of a transparent conductive material, and an upper layer may be made of a metal.

The second electrode 129 of the storage capacitor may be formed of a transparent conductive material such as ITO, IZO, or ZnO, or may be formed of a metal or a conductive polymer.

When the gate electrodes 124d and 124s are formed in a dual-layer structure including a transparent conductive material layer and a metal layer and when the second electrode 129 is formed of a transparent conductive material, these electrodes may be formed by stacking a transparent conductive material, forming a metal layer through a deposition method such as a sputtering method, and patterning the transparent conductive material and the metal layer through a photolithography process using a half-tone mask and an etching process. In this case, impurity doping for forming the source regions 1543d and 1543s and the drain regions 1545d and 1545s of the semiconductor layers 154d and 154s of the driving and switching thin-film transistors DT and ST and the first electrode 154c of the storage capacitor Cst may be performed after the gate electrodes 124d and 124s and the second electrode 129 are formed through patterning.

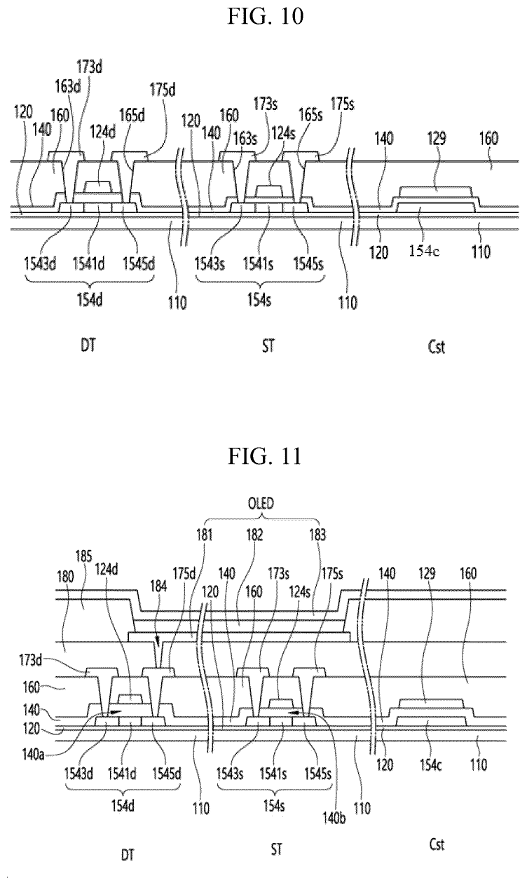

As shown in FIG. 10, an interlayer insulating layer 160 is formed on the entire surface of the substrate, which includes the gate electrode 124d of the driving thin-film transistor DT, the gate electrode 124s of the switching thin-film transistor ST, and the second electrode 129 of the storage capacitor Cst.

In addition, contact holes 163d, 165d, 163s, and 165s for connection of the source electrodes 173d and 173s and the drain electrodes 175d and 175s of the driving and switching thin-film transistors DT and ST are formed through photolithography process and an etching process.

The interlayer insulating layer 160 may be an inorganic insulating layer formed of a material selected from among SiOₓ, SiNₓ, SiONₓ, Al₂O₃, TiO, Ta₂O₅, HfO₂, ZrO₂, BST, and PZT. The interlayer insulating layer 160 is formed to a sufficient thickness to serve as an insulating layer between the gate electrodes 124d and 124s, the source electrodes 173d and 173s, and the drain electrodes 175d and 175s. Meanwhile, the interlayer insulating layer 160 may be an organic insulating layer, rather than an inorganic insulating layer, or may have a structure in which an organic insulating layer and an inorganic insulating layer are stacked.

After the contact holes 163d, 165d, 163s, and 165s are formed, a metal layer may be deposited through a deposition method such as sputtering, and may be patterned through a photolithography process and an etching process to form the source electrodes 173d and 173s and the drain electrodes 175d and 175s. The source electrodes 173d and 173s and the drain electrodes 175d and 175s may be formed in a multilayer structure including, for example, Ti/Al/Ti layers.

As shown in FIG. 11, a planarization layer 180 is formed on the entire surface of the substrate, which includes the source electrodes 173d and 173s and the drain electrodes 175d and 175s. The planarization layer 180 may be formed as an organic insulating layer.

A contact hole 184 is formed by removing the planarization layer 180 through a photolithography process and an etching process to expose the drain electrode 175d of the driving thin-film transistor DT.

Subsequently, a first electrode 181 of the organic light-emitting diode is formed on the planarization layer 180 to be electrically connected to the drain electrode 175d of the driving thin-film transistor DT through the contact hole 184.

A bank layer 185 for defining each sub-pixel region is formed on the planarization layer 180, and an organic light emission layer 182 is formed on the first electrode 181. Subsequently, a second electrode 183 of the organic light-emitting emitting diode is formed on the entire surfaces of the bank layer 185 and the organic light emission layer 182.

According to the display panel and the method of manufacturing the same according to the present disclosure described above, it is possible to adjust the thickness of the gate insulating layer 140a of the driving thin-film transistor DT and the mobility of the driving thin-film transistor DT, thereby reducing the K-factor.

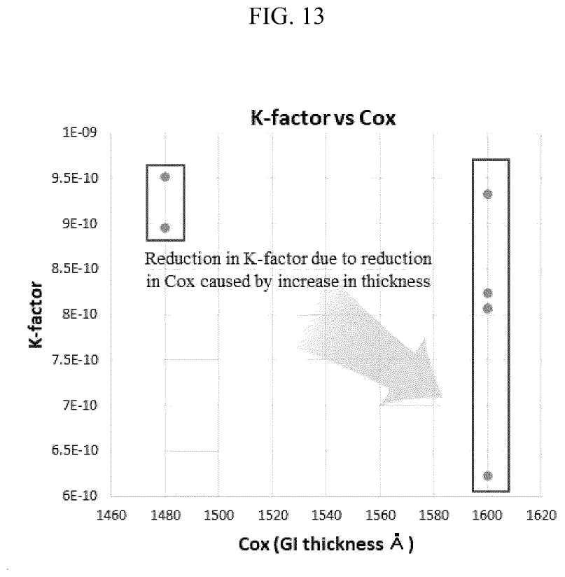

FIG. 13 is a graph showing change in K-factor depending on the thickness of the gate insulating layer of the driving thin-film transistor according to the present disclosure.

The K-factor of the driving thin-film transistor was calculated while varying the thickness of the gate insulating layer of the driving thin-film transistor DT. As shown, it can be seen that the K-factor decreases as the thickness of the gate insulating layer of the driving thin-film transistor DT increases.

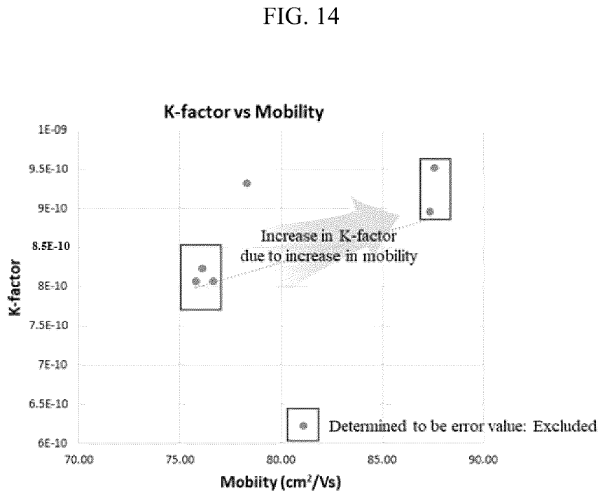

FIG. 14 is a graph showing change in K-factor depending on the mobility of the driving thin-film transistor according to the embodiment of the present disclosure.

The K-factor of the driving thin-film transistor was calculated while varying the mobility of the driving thin-film transistor DT. As shown, it can be seen that the K-factor increases as the mobility of the driving thin-film transistor DT increases.

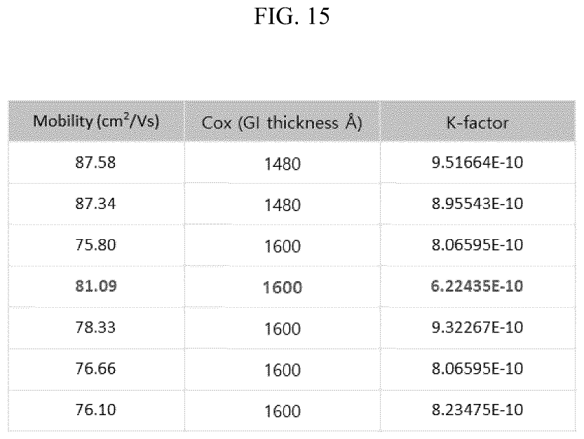

FIG. 15 is a table showing change in K-factor depending on the mobility of the driving thin-film transistor and the thickness of the gate insulating layer according to the embodiment of the present disclosure.

In an experiment for calculating the K-factor while varying the mobility of the driving thin-film transistor DT under the condition that the thickness of the gate insulating layer of the driving thin-film transistor DT is set to 1480 Å and 1600 Å, it can be seen that the lowest K-factor is obtained when the thickness of the gate insulating layer of the driving thin-film transistor DT is 1600 Å and the mobility of the driving thin-film transistor DT is 81.09 cm²/Vs.

Therefore, according to the display panel and the method of manufacturing the same according to the present disclosure, the K-factor may be reduced when the thickness of the gate insulating layer of the driving thin-film transistor DT ranges from 1500 Å to 1700 Å and the mobility of the driving thin-film transistor DT ranges from 79 cm²/Vs to 82 cm²/Vs.

Therefore, in order to ensure the mobility of the driving thin-film transistor DT in the range from 79 cm²/Vs to 82 cm²/Vs, it is preferable to perform heat treatment for 10 to 20 minutes at a temperature ranging from 370° C. to 374° C. within the temperature and time ranges described with reference to FIG. 12.

In addition, since the gate insulating layer of the driving thin-film transistor is thicker than the gate insulating layer of the switching thin-film transistor and the semiconductor layer of the switching thin-film transistor is not dehydrogenated, the driving thin-film transistor has a smaller K-factor than the switching thin-film transistor.

As is apparent from the above description, the display panel and the method of manufacturing the same according to the embodiments of the present disclosure having the above-described characteristics have the following effects.

Since the thickness of the gate insulating layer of the driving thin-film transistor and the mobility of the driving thin-film transistor are adjusted to reduce the K-factor, it is possible to reduce variation in the current Ids of the driving thin-film transistor attributable to distribution of the gate-source voltage Vgs of the driving thin-film transistor DT and the threshold voltage Vth of the driving thin-film transistor DT.

Therefore, it is possible to prevent mura at the time of low grayscale driving by reducing the current (Ids) sensitivity of the driving thin-film transistor.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display panel, comprising:
a plurality of sub-pixels, each having a driving thin-film transistor, a switching thin-film transistor, and a storage capacitor on a substrate,
wherein the driving thin-film transistor comprises:
a semiconductor layer comprising a source region and a drain region;
a gate electrode overlapping the semiconductor layer;
a source electrode and a drain electrode electrically connected to the source region and the drain region respectively; and
a gate insulating layer located between the semiconductor layer and the gate electrode, and
wherein the semiconductor layer is a dehydrogenated semiconductor layer.

2. The display panel according to claim 1, wherein the semiconductor layer has a mobility of 79 cm²/Vs to 82 cm²/Vs.

3. The display panel according to claim 1, wherein the gate insulating layer of the driving thin-film transistor has a thickness different from a gate insulating layer of the switching thin-film transistor.

4. The display panel according to claim 3, wherein the gate insulating layer of the driving thin-film transistor has a thickness of 1500 Å to 1700 Å, and the gate insulating layer of the switching thin-film transistor has a thickness of 1380 Å to 1580 Å.

5. The display panel according to claim 1, wherein the driving thin-film transistor has a smaller K-factor than the switching thin-film transistor.

6. The display panel according to claim 1, wherein each of the plurality of sub-pixels further comprises an organic light-emitting diode electrically connected to the drain electrode of the driving thin-film transistor.

7. The display panel according to claim 1, wherein the dehydrogenated semiconductor layer is in a state in which hydrogen bonded to a surface of the semiconductor layer is removed by heat treatment.

8. A method of manufacturing a display panel, the method comprising:
forming a semiconductor layer on a substrate;
patterning the semiconductor layer to form a first semiconductor layer for a driving thin-film transistor and a second semiconductor layer for a switching thin-film transistor;
performing heat treatment for dehydrogenation on the first semiconductor layer to remove hydrogen coupled to a surface of the first semiconductor layer;
forming a gate insulating layer on an entire surface of the substrate having the first and second semiconductor layers formed thereon; and
etching a remaining portion of the gate insulating layer, except for a portion of the gate insulating layer over the first semiconductor layer, to a predetermined depth.

9. The method according to claim 8, wherein the gate insulating layer of the driving thin-film transistor is formed to have a thickness of 1500 Å to 1700 Å, and the gate insulating layer of the switching thin-film transistor is formed to have a thickness of 1380 Å to 1580 Å.

10. The method according to claim 8, wherein the first semiconductor layer is subjected to heat treatment for 10 to 20 minutes at a temperature ranging from 370° C. to 374° C.

11. The method according to claim 8, wherein the first semiconductor layer has a mobility of 79 cm²/Vs to 82 cm²/Vs.

12. A display panel comprising:
a plurality of sub-pixels, each having a driving thin-film transistor, a switching thin-film transistor, and a storage capacitor on a substrate,
wherein the driving thin-film transistor and the switching thin-film transistor each comprise a semiconductor layer, a gate electrode, and a gate insulating layer located between the semiconductor layer and the gate electrode,
wherein the gate insulating layer of the driving thin-film transistor is formed to be thicker than the gate insulating layer of the switching thin-film transistor, and
the semiconductor layer of the driving thin-film transistor is a dehydrogenated semiconductor layer.

13. The display panel according to claim 12, wherein the semiconductor layer of the driving thin-film transistor has a mobility of 79 cm²/Vs to 82 cm²/Vs.

14. The display panel according to claim 12, wherein the gate insulating layer of the driving thin-film transistor is 120 Å thicker than the gate insulating layer of the switching thin-film transistor.

15. The display panel according to claim 14, wherein the gate insulating layer of the driving thin-film transistor has a thickness of 1500 Å to 1700 Å, and the gate insulating layer of the switching thin-film transistor has a thickness of 1380 Å to 1580 Å
